(19) United States
(12) Patent Application Publication
(10) Pub. No.: US 2026/0254419 A1
(43) Pub. Date: Aug. 27, 2026

(54) BIAS CIRCUIT FOR CLASS C AMPLIFIERS

(71) Applicant: QUALCOMM Incorporated, San Diego, CA (US)

(72) Inventors: Sunbo SHIM, San Diego, CA (US); Muslum Emir AVCI, Marlborough, MA (US); Jing-Hwa CHEN, Sudbury, MA (US); Antonino SCUDERI, San Diego, CA (US)

(21) Appl. No.: 19/063,178

(22) Filed: Feb. 25, 2025

(51) Int. Cl. H03F 1/30; H03F 1/02; H03F 3/24

(52) U.S. Cl. CPC H03F 1/302; H03F 1/0288; H03F 3/245; H03F 2200/451

(57) ABSTRACT

Bias circuits are provided for biasing an amplifier transistor in load-modulated amplifiers such as a class C amplifier. In a first bias circuit, a current source drives a reference current into a first node coupled to a second node through a first resistor. The first node couples to a collector of a first bipolar junction transistor and to a base of a second bipolar junction transistor. The second node coupled to a base of a third bipolar junction transistor.

### TECHNICAL FIELD

The present application relates generally to amplifiers and more specifically, to a class C amplifier bias circuit.

### BACKGROUND

Amplifiers are classified depending upon their biasing. In a class C amplifier, an amplifier transistor is biased so that its output current is zero over more than one half of an input signal's sinusoidal cycle (the conduction angle being less than 180 degrees). Due to their high efficiency, class C amplifiers have numerous applications. For example, the peaking or auxiliary amplifier in a Doherty amplifier is typically biased to form a class C amplifier.

The peaking amplifier in a Doherty amplifier is often made using a hetero bipolar junction transistor (HBT) due to its advantageous high-frequency properties. A bias circuit biases the base of the HBT with a bias voltage that is less than the base-to-emitter voltage so that the desired limited conduction angle is achieved. The bias circuit should be relatively low power, compact, and robust to process, voltage, and temperature variations.

### SUMMARY

In accordance with an aspect of the disclosure, an apparatus is provided that includes: a bias circuit, the bias circuit including: a current source configured to drive a reference current into a first node; a first bipolar junction transistor coupled between the first node and ground; a first resistor coupled between the first node and a second node; a second resistor; a second bipolar junction transistor having a collector coupled to the second node, a base coupled to the first node, and an emitter coupled to ground through the second resistor; and a third bipolar junction transistor having a base coupled to the second node; and an amplifier including a fourth bipolar junction transistor, wherein an emitter of the third bipolar junction transistor is coupled to a base of the fourth bipolar junction transistor to bias the fourth bipolar junction transistor.

In accordance with another aspect of the disclosure, an apparatus is provided that includes: a bias circuit, the bias circuit including: a current source configured to drive a reference current into a first node; a first resistor coupled between the first node and a second node; a first bipolar junction transistor coupled between the second node and ground; a second bipolar junction transistor having a base coupled to the first node and a collector coupled to the second node; a second resistor coupled in series with a third resistor between a collector of the second bipolar junction transistor and ground, wherein a node between the second resistor and the third resistor couples to a base of the first bipolar junction transistor; and a third bipolar junction transistor having a base coupled to the second node; and an amplifier including a fourth bipolar junction transistor, wherein an emitter of the third bipolar junction transistor is coupled to a base of the fourth bipolar junction transistor to bias the fourth bipolar junction transistor.

Finally, in accordance with yet another aspect of the disclosure, a method of biasing is provided that includes: conducting a current from a current source into a first node coupled to a collector of a first bipolar junction transistor and to a base of a second bipolar junction transistor to charge the first node; conducting a portion of the current from the first node through a resistor to a second node coupled to a collector of the second bipolar junction transistor to charge the second node to a base voltage; biasing a base of a third bipolar junction transistor with the base voltage to develop a bias voltage at an emitter of the third bipolar junction transistor; and biasing a base of a fourth bipolar junction transistor with the bias voltage.

These and other advantageous features may be better appreciated through the following detailed description.

### BRIEF DESCRIPTION OF THE DRAWINGS

FIG. 1 illustrates a first bias circuit for biasing a class C amplifier transistor in accordance with an aspect of the disclosure.

FIG. 2 illustrates a second bias circuit for biasing a class C amplifier transistor in accordance with an aspect of the disclosure.

FIG. 3 illustrates a third bias circuit for biasing a class C amplifier transistor in accordance with an aspect of the disclosure.

FIG. 4 illustrates a fourth bias circuit for biasing a class C amplifier transistor in accordance with an aspect of the disclosure.

FIG. 5 illustrates a fifth bias circuit for biasing a class C amplifier transistor in accordance with an aspect of the disclosure.

FIG. 6 illustrates a Doherty amplifier in which the auxiliary amplifier transistor is biased by a bias circuit in accordance with an aspect of the disclosure.

FIG. 7 illustrates a transceiver in which the power amplifier is a Doherty amplifier including an auxiliary amplifier biased by a bias circuit in accordance with an aspect of the disclosure.

FIG. 8 is a flowchart for a method of biasing an amplifier transistor in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

To provide a conduction angle of less than 180° in a a bipolar-junction-transistor-based Class C amplifier, a bias circuit biases the base of an amplifier bipolar junction transistor (BJT) with a bias voltage equaling a fraction of the active-region base-to-emitter voltage (VBE). The BJT will thus operate in the active region only for higher amplitudes of an input signal being amplified by the class C amplifier so that the reduced conduction angle is achieved. To generate the bias voltage, the bias circuit may include a current source that drives a reference current into a first diode-connected BJT that has an emitter coupled to ground through a resistor. An emitter voltage of the first BJT thus equals a product Iref*R, where Iref is the reference current and R is the resistance of the resistor. It follows that a base voltage of the first BJT will equal VBE plus the Iref*R. This base voltage biases the base of a second BJT. An emitter voltage of the second BJT thus equals the product Iref*R. Through an appropriate selection of the reference current Iref and the resistance R, the emitter voltage of the second BJT equals the desired fraction of VBE so that the emitter voltage may function as a bias voltage to bias the base of an amplifier BJT to operate with the desired reduced conduction angle. However, the generation of the reference current and the resistance of the resistor are both subject to process, voltage, and temperature (PVT) variations. The resulting PVT variations in the bias voltage undesirably degrade the class C amplifier performance such as characterized through the adjacent channel leakage ratio (ACLR) or another suitable amplifier performance parameter.

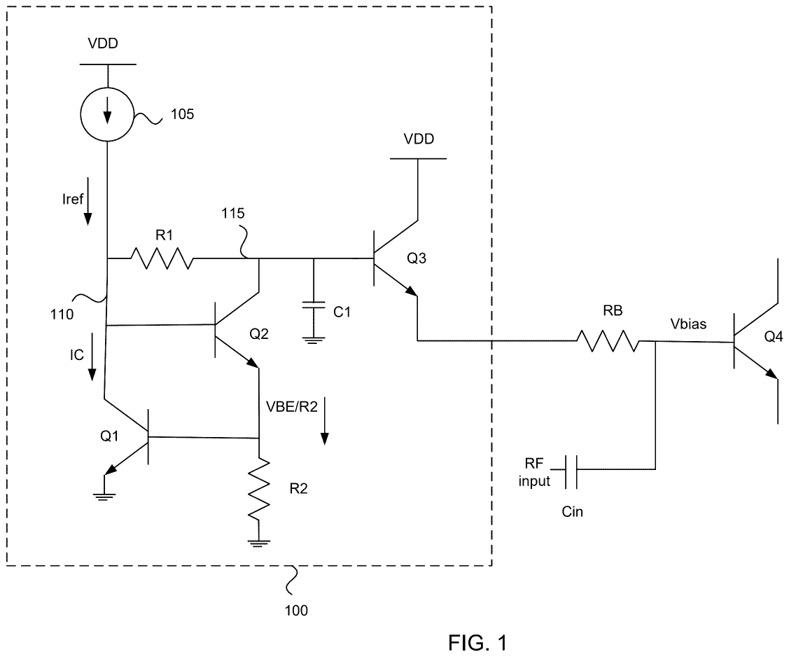

An improved bias circuit 100 is provided as shown in FIG. 1 in which the effects of the PVT variations in the reference current and resistance on the bias voltage are substantially eliminated. The bias circuit 100 includes a current source 105 that drives a reference current (Iref) into a first node 110. A first BJT Q1 has a collector coupled to the first node 110 and an emitter coupled to ground. A first resistor R1 couples between the first node 110 and a second node 115. A second BJT Q2 has a collector coupled to the second node 115, a base coupled to the first node 110, and an emitter coupled to ground through a second resistor R2.

The reference current Iref has a magnitude sufficient to ensure that the first BJT Q1 and the second BJT Q2 both operate in the active region. A base voltage of the first BJT Q1 thus equals VBE, which forces the second BJT Q2 to conduct an emitter current of VBE/R2, where R2 is also represents the resistance of the resistor R2. Since a voltage of the first node 110 equals 2 VBE, a voltage of the second node 115 equals approximately 2 VBE−VBE*R1/R2 (ignoring the base currents of Q1 and Q2). The second node 115 couples to a base of a third BJT Q3. An emitter voltage of the third BJT Q3 thus equals VBE*(1−R1/R2). The emitter of the third BJT Q3 couples through a base resistor RB to a base of a class C amplifier BJT Q4. The base of the class C amplifier transistor M4 is thus biased to a bias voltage of VBE*(1−R1/R2) (disregarding the minor effect of the base current for the class C amplifier transistor Q4 and the resulting Ohmic voltage across the base resistor). The class C amplifier transistor M4 is thus biased with a bias voltage that advantageously tracks the temperature variations of the base-to-emitter voltage for the class C amplifier transistor Q4. In addition, since the bias voltage is a fraction of VBE, a class C biasing is achieved as desired. Note that to a first order, the bias voltage has no dependence on the reference current magnitude. In addition, any PVT in the resistance variations of R1 and R2 will be substantially eliminated by their division to form the ratio R1/R2.

The doping of the transistors Q1, Q2, and Q3 may match the doping (NPN or PNP) of the class C amplifier transistor Q4. In addition, the transistors Q1, Q2, Q3, and Q4 may each comprise an HBT. The following discussion will assume that transistors Q1, Q2, and Q2 are NPN transistors but it will be appreciated that these transistors may be doped to be PNP transistors in an alternative implementation. The class C amplifier transistor Q4 functions to amplify an RF input signal that couples to the base of the class C amplifier transistor Q4 through a DC blocking capacitor Cin. To prevent this RF input signal from affecting the bias voltage, the base of the transistor Q3 couples to ground through a capacitor C1. In this fashion, any RF noise from the RF input signal at the base of the transistor Q3 is discharged to ground through the capacitor C1. In some implementations, the resistors R1 and R2 may be variable resistors.

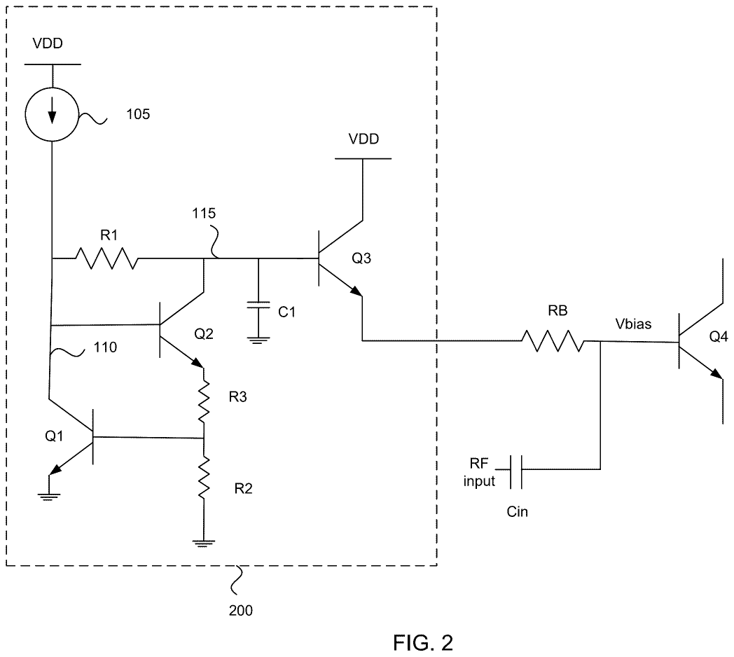

The bias circuit 100 may be modified such as shown for a bias circuit 200 of FIG. 2. Bias circuit 200 includes a resistor R3 that couples between the emitter of the BJT Q2 and the base of the BJT Q1. The remaining components of the bias circuit 200 are arranged as discussed for the bias circuit 100. To a first order, the bias voltage from the bias circuit 200 will thus equal the bias voltage from the bias circuit 100 and offer the same advantageous independence from PVT variations in the reference current generation and the resistances.

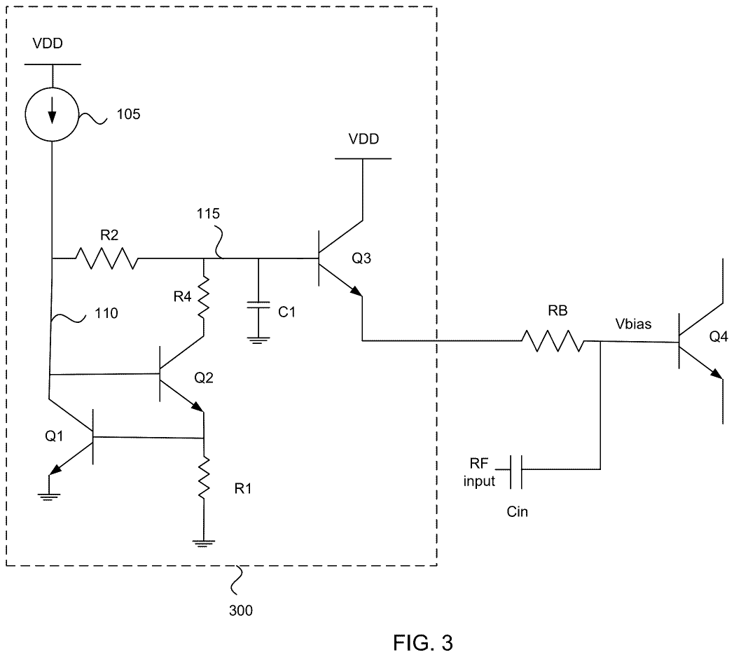

The bias circuit 100 may also be modified as shown for a bias circuit 300 of FIG. 3. Bias circuit 300 includes a resistor R4 that couples between the node 115 and the collector of the BJT Q2. The remaining components of the bias circuit 300 are arranged as discussed for the bias circuit 100. To a first order, the bias voltage from the bias circuit 300 will thus equal the bias voltage from the bias circuit 100 and offer the same advantageous independence from PVT variations in the reference current generation and the resistances.

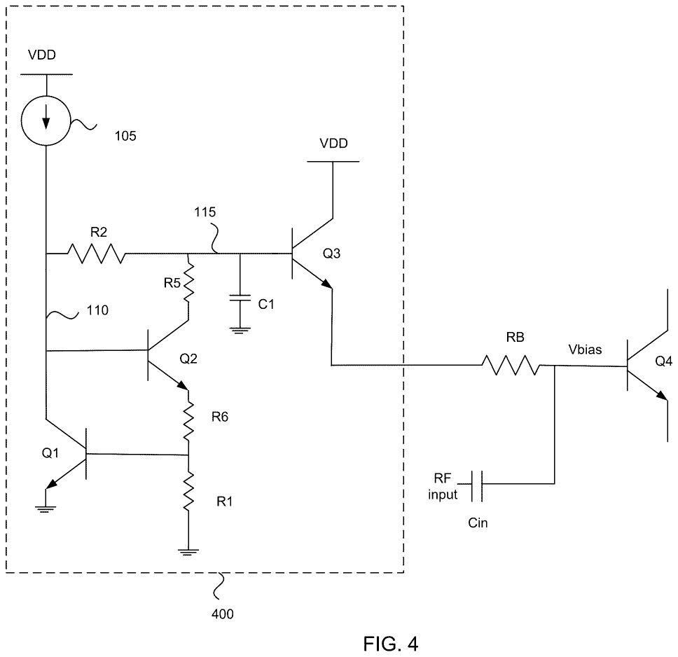

The bias circuit 100 may also be modified as shown for a bias circuit 400 of FIG. 4. Bias circuit 400 includes a resistor R5 that couples between the node 115 and the collector of the BJT Q2. In addition, the bias circuit 400 includes a resistor R6 that couples between the emitter of the BJT Q2 and the base of the BJT Q1. The remaining components of the bias circuit 400 are arranged as discussed for the bias circuit 100. To a first order, the bias voltage from the bias circuit 400 will thus equal the bias voltage from the bias circuit 100 and offer the same advantageous independence from PVT variations in the reference current generation and the resistances.

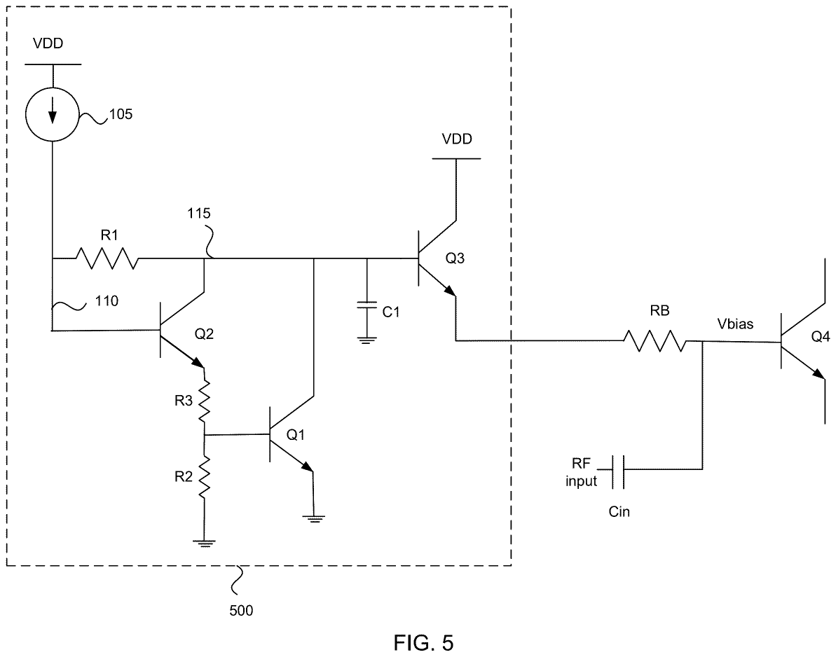

Yet another bias circuit 500 is shown in FIG. 5. Bias circuit 500 includes the resistor R1, R2, and R3 and also the BJT Q2 arranged as discussed for the bias circuit 200. However, the BJT Q1 is displaced to have its collector coupled to the node 115 and its base coupled to a node between the resistors R2 and R3. To a first order, the bias voltage from the bias circuit 500 will thus equal the bias voltage from the bias circuit 200 and offer the same advantageous independence from PVT variations in the reference current generation and the resistances.

An example class C amplifier application that is advantageously biased by a bias circuit as disclosed herein will now be discussed. For example, the high peak-to-average-power-ratio (PAPR) of orthogonal frequency division multiplexing (OFDM) such as used in fifth generation (5G) telecommunication systems poses a dilemma for amplifiers. Should an amplifier be biased for efficient operation at the peak power of an OFDM signal, the amplifier will then operate with poor efficiency while the OFDM signal power is below this peak power. This lower efficiency would then be particularly problematic since the majority of the signal transmission occurs with the OFDM signal power below the peak power. Should the amplifier instead be biased for efficient operation at the average power of the OFDM signal, clipping or saturation then occurs when the OFDM signal transitions to its peak power.

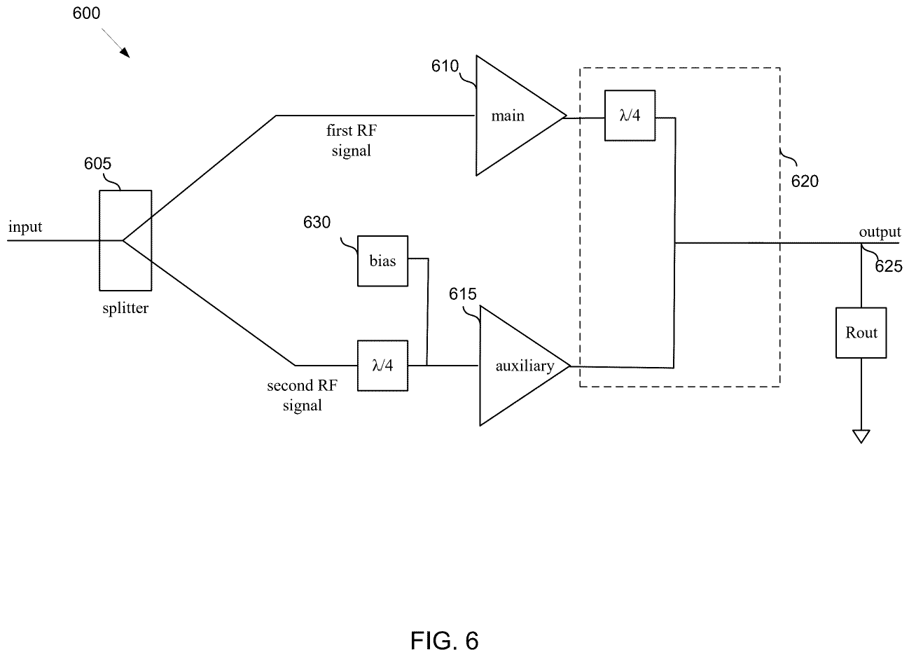

A Doherty amplifier solves this dilemma because a Doherty amplifier includes a main amplifier and an auxiliary amplifier that combine for peak efficiency not only at the average power of the radio frequency (RF) input signal but also at peak power of the RF input signal. An example Doherty amplifier 600 is illustrated in FIG. 6. An RF input signal (input) is split (e.g., split equally) in a splitter 605 into a first RF signal and a second RF signal. The first RF signal propagates over a first transmission line having a first electrical length to form a first input signal to a main amplifier 610. The second RF signal propagates over a second transmission line to form a second input signal to an auxiliary amplifier 615. The second transmission line has a second electrical length (e.g., potentially implemented by a phase shifter or other technique) that is greater than the first electrical length by λ/4, where λ is the carrier wavelength of the RF input signal. Given this electrical length difference for the propagation of the first and second split signals, a current conducted by the main amplifier 610 at peak power is delayed in phase by 90° (a quadrature phase relationship) with respect to a current conducted by the auxiliary amplifier 615 at peak power.

A bias circuit (not illustrated) biases the main amplifier 610 to be efficient for the average power of the RF input signal. For example, the main amplifier 610 may be biased to function as a class B (or a class AB) amplifier. In contrast, a bias circuit 630 as disclosed herein biases an amplifier transistor (not illustrated) in the auxiliary amplifier 615 for class C operation. The BJT Q4 discussed earlier is an example of such an amplifier transistor. Bias circuit 630 may be implemented as discussed for any of the bias circuits 100, 200, 300, 400, and 500.

A combining network 620 combines the output signals from each of the main amplifier 610 and the auxiliary amplifier 615 to produce a combined RF output signal (output) at an output node 625. The combining network 620 includes an output transmission line extending from an output terminal of the main amplifier 610 to a combining node 625. This output transmission line has an electrical length that is longer by λ/4 than an output transmission line from an output terminal of the auxiliary amplifier 615 to the node 625. Node 625 is loaded by an output load Rout. The bias circuit 630 biases the auxiliary amplifier 615 so that the auxiliary amplifier 615 cuts off, for example, at 6 dB from the peak power of the RF output signal. It will be appreciated that the Doherty amplifier 600 is but one example of a Doherty amplifier architecture and may be modified in alternative implementations. For example, the phase relationship may be varied from a quadrature relationship in both the splitter 605 and the combining network 620. In addition, a pre-driver amplifier and/or a driver amplifier may amplify the first RF signal prior to its amplification by the main amplifier 610. Similarly, another pre-driver amplifier and/or a driver amplifier may amplify the second RF signal prior to its amplification by the auxiliary amplifier 615. More generally, the bias circuit 630 may be advantageously used to bias other types of load-modulated amplifiers such as a load-modulated balanced amplifier.

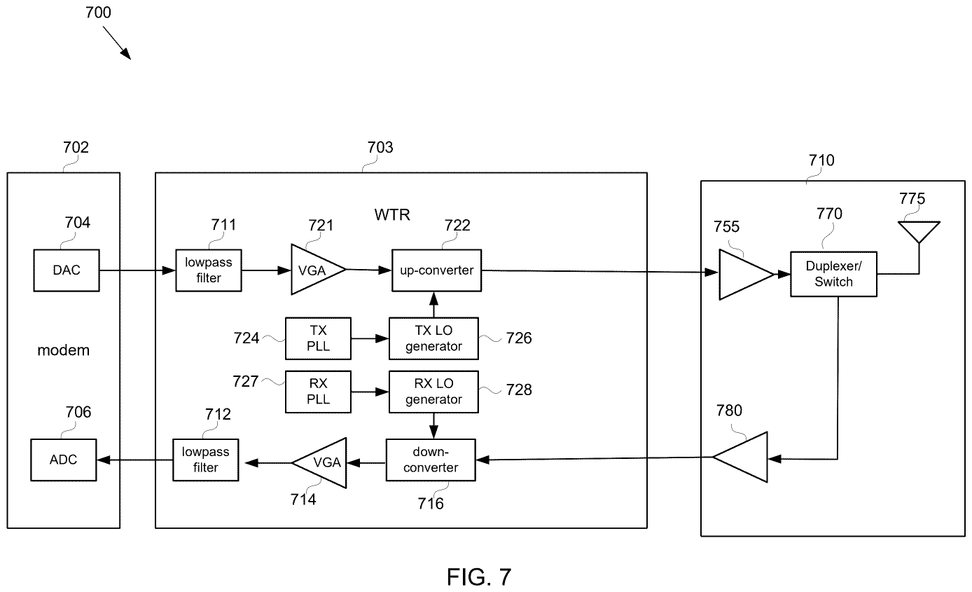

An amplifier including a bias circuit as disclosed herein may be advantageously incorporated into any suitable transceiver within a wireless communication device. An example wireless communication device 700 is shown in FIG. 7. A modem 702 (which may also be denoted as a baseband processor) includes at least one digital-to-analog converter (DAC) 704 for generating an analog transmit signal. A wireless transceiver integrated circuit (WTR) 703 includes a lowpass filter 711 for filtering the analog transmit signal to provide a filtered analog signal to a variable gain amplifier (VGA) 721. An up-converter 722 (such as one or more mixers) up converts an amplified analog signal from the VGA 721 in frequency to produce an RF signal. For example, the up-converter 722 may mix the amplified analog signal with a local oscillator (LO) signal from a transmit (TX) LO generator 726 to form an RF input signal to a front-end module 710. An oscillator such as a TX phase-locked loop (PLL) 724 clocks the TX LO generator 726 for the generation of the TX LO signal.

The front-end module 710 includes a power amplifier 755 for amplifying the RF input signal. It will be appreciated that additional stages of amplification of the RF input signal prior to the power amplifier 755 such as a pre-driver amplifier (not illustrated) and a driver amplifier (not illustrated) may also be used in alternative implementations. The power amplifier 755 may be implemented as a Doherty amplifier that is biased as discussed with respect to FIG. 6. An amplified RF output signal from the power amplifier 755 passes through an antenna switch module (duplexer/switch) 770 to an antenna(s) 775 for wireless transmission.

During a receive mode, a received RF signal from the antenna(s) 775 passes through the antenna switch module 770 to a low-noise amplifier 780. A down-converter 716 (such as one or more mixers) down converts an amplified RF signal from the low-noise amplifier 780 in frequency to produce a down-converted analog signal. For example, the down-converter 716 may mix the amplified RF signal with an LO signal from a receive (RX) LO generator 728. An oscillator such as an RX phase-locked loop (PLL) 727 clocks the RX LO generator 728 for the generation of the RX LO signal. Another VGA 714 amplifies the down-converted analog signal from the down-converter 716 to drive a lowpass filter 712 that provides a filtered analog signal to an analog-to-digital (ADC) 706 in modem 702. The analog-to-digital converter (ADC) 706 recovers the digital baseband signal for further processing by modem 702. It will be appreciated that WTR 703 is merely exemplary and that other transceiver architectures may be used in conjunction with the class C amplifier biasing disclosed herein.

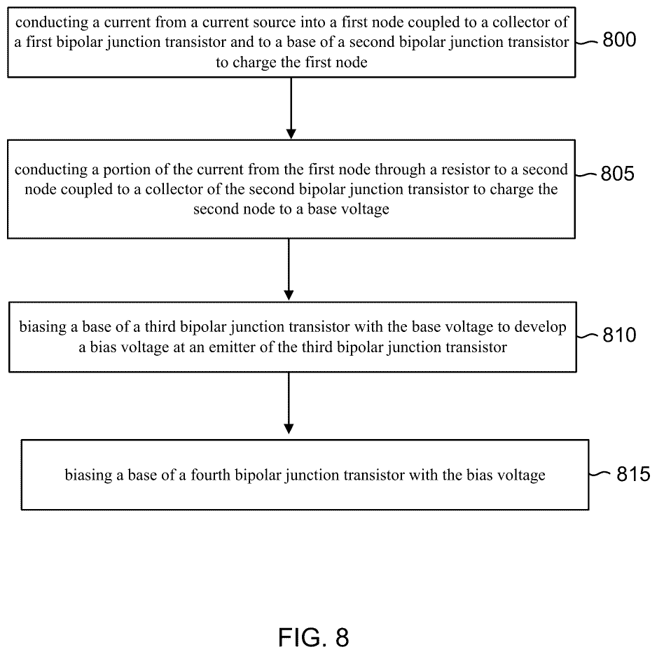

An example method of biasing will now be discussed with respect to the flowchart of FIG. 8. The method includes an act 800 of conducting a current from a current source into a first node coupled to a collector of a first bipolar junction transistor and to a base of a second bipolar junction transistor to charge the first node. The conduction of the reference current into the first node 110 of the bias circuit 100, 200, 300, or 400 is an example of act 800. The method also includes an act 805 of conducting a portion of the current from the first node through a resistor to a second node coupled to a collector of the second bipolar junction transistor to charge the second node to a base voltage. The conduction through the first resistor in the bias circuit 100, 200, 300, or 400 is an example of act 805. The method further includes an act 810 of biasing a base of a third bipolar junction transistor with the base voltage to develop a bias voltage at an emitter of the third bipolar junction transistor. The development of the base voltage for the BJT Q3 in the bias circuit 100, 200, 300, or 400 is an example of act 810. Finally, the method also includes an act 815 of biasing a base of a fourth bipolar junction transistor with the bias voltage. The biasing of the BJT Q4 by the bias circuit 100, 200, 300, or 400 is an example of act 815.

Some example implementations will now be summarized through the following numbered clauses:

Clause 1. An apparatus, comprising:
a bias circuit, the bias circuit including:
   a current source configured to drive a reference current into a first node;
   a first bipolar junction transistor coupled between the first node and ground;
   a first resistor coupled between the first node and a second node;
   a second resistor;
   a second bipolar junction transistor having a collector coupled to the second node, a base coupled to the first node, and an emitter coupled to ground through the second resistor; and
   a third bipolar junction transistor having a base coupled to the second node; and
an amplifier including a fourth bipolar junction transistor, wherein an emitter of the third bipolar junction transistor is coupled to a base of the fourth bipolar junction transistor to bias the fourth bipolar junction transistor.

Clause 2. The apparatus of clause 1, wherein the bias circuit further includes:
a capacitor coupled between the base of the third bipolar junction transistor and ground.

Clause 3. The apparatus of any of clauses 1-2, wherein the bias circuit further includes:
a third resistor coupled between the emitter of the second bipolar junction transistor and the second resistor.

Clause 4. The apparatus of any of clauses 1-2, wherein the bias circuit further includes:
a fourth resistor coupled between the collector of the second bipolar junction transistor and the second node.

Clause 5. The apparatus of any of clauses 1-2, wherein the bias circuit further includes:
a third resistor coupled between the emitter of the second bipolar junction transistor and the second resistor; and
a fourth resistor coupled between the collector of the second bipolar junction transistor and the second node.

Clause 6. The apparatus of any of clauses 1-5, wherein each of the first bipolar junction transistor, the second bipolar junction transistor, the third bipolar junction transistor, and the fourth bipolar junction transistor comprises a hetero bipolar junction transistor.

Clause 7. The apparatus of clause 6, wherein each hetero bipolar junction transistor comprises an NPN hetero bipolar junction transistor.

Clause 8. The apparatus of any of clauses 1-7, wherein the amplifier is an auxiliary amplifier in a Doherty amplifier.

Clause 9. The apparatus of clause 8, wherein the Doherty amplifier is a power amplifier in a wireless transceiver.

Clause 10. The apparatus of any of clauses 1-9, wherein the amplifier further includes a DC-blocking capacitor coupled between a node for an input signal and the base of the fourth bipolar junction transistor.

Clause 11. The apparatus of clause 10, wherein the amplifier further includes a base resistor coupled between the emitter of the third bipolar junction transistor and the base of the fourth bipolar junction transistor.

Clause 12. The apparatus of any of clauses 1-10, wherein a collector of the third bipolar junction transistor is coupled to a node for a power supply voltage.

Clause 13. The apparatus of any of clauses 1-12, wherein the first resistor and the second resistor each comprises a variable resistor.

Clause 14. An apparatus, comprising:
a bias circuit, the bias circuit including:
   a current source configured to drive a reference current into a first node;
   a first resistor coupled between the first node and a second node;
   a first bipolar junction transistor coupled between the second node and ground;
   a second bipolar junction transistor having a base coupled to the first node and a collector coupled to the second node;
   a second resistor coupled in series with a third resistor between a collector of the second bipolar junction transistor and ground, wherein a node between the second resistor and the third resistor couples to a base of the first bipolar junction transistor; and
   a third bipolar junction transistor having a base coupled to the second node; and
an amplifier including a fourth bipolar junction transistor, wherein an emitter of the third bipolar junction transistor is coupled to a base of the fourth bipolar junction transistor to bias the fourth bipolar junction transistor.

Clause 15. The apparatus of clause 14, wherein the bias circuit further includes:
a capacitor coupled between the base of the third bipolar junction transistor and ground.

Clause 16. The apparatus of any of clauses 14-15, wherein the amplifier is an auxiliary amplifier in a Doherty amplifier.

Clause 17. The apparatus of clause 14, wherein the first bipolar junction transistor, the second bipolar junction transistor, the third bipolar junction transistor, and the fourth bipolar junction transistor each comprises an NPN hetero bipolar junction transistor.

Clause 18. The apparatus of clause 14, wherein the amplifier further includes a base resistor coupled between the emitter of the third bipolar junction transistor and the base of the fourth bipolar junction transistor.

Clause 19. A method of biasing, comprising:
conducting a current from a current source into a first node coupled to a collector of a first bipolar junction transistor and to a base of a second bipolar junction transistor to charge the first node;
conducting a portion of the current from the first node through a resistor to a second node coupled to a collector of the second bipolar junction transistor to charge the second node to a base voltage; and
biasing a base of a third bipolar junction transistor with the base voltage to develop a bias voltage at an emitter of the third bipolar junction transistor; and
biasing a base of a fourth bipolar junction transistor with the bias voltage.

Clause 20. The method of clause 19, further comprising: coupling a radio frequency input signal to the base of the fourth bipolar junction transistor to amplify the radio frequency input signal.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. An apparatus, comprising:
a bias circuit, the bias circuit including:
a current source configured to drive a reference current into a first node;
a first bipolar junction transistor coupled between the first node and ground;
a first resistor coupled between the first node and a second node;
a second resistor;
a second bipolar junction transistor having a collector coupled to the second node, a base coupled to the first node, and an emitter coupled to ground through the second resistor; and
a third bipolar junction transistor having a base coupled to the second node; and
an amplifier including a fourth bipolar junction transistor, wherein an emitter of the third bipolar junction transistor is coupled to a base of the fourth bipolar junction transistor to bias the fourth bipolar junction transistor.

2. The apparatus of claim 1, wherein the bias circuit further includes:
a capacitor coupled between the base of the third bipolar junction transistor and ground.

3. The apparatus of claim 1, wherein the bias circuit further includes:
a third resistor coupled between the emitter of the second bipolar junction transistor and the second resistor.

4. The apparatus of claim 1, wherein the bias circuit further includes:
a fourth resistor coupled between the collector of the second bipolar junction transistor and the second node.

5. The apparatus of claim 1, wherein the bias circuit further includes:
a third resistor coupled between the emitter of the second bipolar junction transistor and the second resistor; and
a fourth resistor coupled between the collector of the second bipolar junction transistor and the second node.

6. The apparatus of claim 1, wherein each of the first bipolar junction transistor, the second bipolar junction transistor, the third bipolar junction transistor, and the fourth bipolar junction transistor comprises a hetero bipolar junction transistor.

7. The apparatus of claim 6, wherein each hetero bipolar junction transistor comprises an NPN hetero bipolar junction transistor.

8. The apparatus of claim 1, wherein the amplifier is an auxiliary amplifier in a Doherty amplifier.

9. The apparatus of claim 8, wherein the Doherty amplifier is a power amplifier in a wireless transceiver.

10. The apparatus of claim 1, wherein the amplifier further includes a DC-blocking capacitor coupled between a node for an input signal and the base of the fourth bipolar junction transistor.

11. The apparatus of claim 10, wherein the amplifier further includes a base resistor coupled between the emitter of the third bipolar junction transistor and the base of the fourth bipolar junction transistor.

12. The apparatus of claim 1, wherein a collector of the third bipolar junction transistor is coupled to a node for a power supply voltage.

13. The apparatus of claim 1, wherein the first resistor and the second resistor each comprises a variable resistor.

14. An apparatus, comprising:
a bias circuit, the bias circuit including:
a current source configured to drive a reference current into a first node;
a first resistor coupled between the first node and a second node;
a first bipolar junction transistor coupled between the second node and ground;
a second bipolar junction transistor having a base coupled to the first node and a collector coupled to the second node;
a second resistor coupled in series with a third resistor between a collector of the second bipolar junction transistor and ground, wherein a node between the second resistor and the third resistor couples to a base of the first bipolar junction transistor; and
a third bipolar junction transistor having a base coupled to the second node; and
an amplifier including a fourth bipolar junction transistor, wherein an emitter of the third bipolar junction transistor is coupled to a base of the fourth bipolar junction transistor to bias the fourth bipolar junction transistor.

15. The apparatus of claim 14, wherein the bias circuit further includes:
a capacitor coupled between the base of the third bipolar junction transistor and ground.

16. The apparatus of claim 14, wherein the amplifier is an auxiliary amplifier in a Doherty amplifier.

17. The apparatus of claim 14, wherein the first bipolar junction transistor, the second bipolar junction transistor, the third bipolar junction transistor, and the fourth bipolar junction transistor each comprises an NPN hetero bipolar junction transistor.

18. The apparatus of claim 14, wherein the amplifier further includes a base resistor coupled between the emitter of the third bipolar junction transistor and the base of the fourth bipolar junction transistor.

19. A method of biasing, comprising:
conducting a current from a current source into a first node coupled to a collector of a first bipolar junction transistor and to a base of a second bipolar junction transistor to charge the first node;
conducting a portion of the current from the first node through a resistor to a second node coupled to a collector of the second bipolar junction transistor to charge the second node to a base voltage;
biasing a base of a third bipolar junction transistor with the base voltage to develop a bias voltage at an emitter of the third bipolar junction transistor; and
biasing a base of a fourth bipolar junction transistor with the bias voltage.

20. The method of claim 19, further comprising:
coupling a radio frequency input signal to the base of the fourth bipolar junction transistor to amplify the radio frequency input signal.
